(19) United States
(12) Patent Application Publication
(10) Pub. No.: US 2010/0109005 A1
(43) Pub. Date: May 6, 2010

(54) SEMICONDUCTOR DEVICE COMPRISING A DISTRIBUTED INTERCONNECTED SENSOR STRUCTURE FOR DIE INTERNAL MONITORING PURPOSES

(76) Inventors: Michael Grillberger, Radebeul (DE); Matthias Lehr, Dresden (DE)

Correspondence Address: WILLIAMS, MORGAN & AMERSON, 10333 RICHMOND, SUITE 1100, HOUSTON, TX, 77042, US

(21) Appl. No.: 12/561,362

(22) Filed: Sep. 17, 2009

(30) Foreign Application Priority Data
Oct. 31, 2008 (DE) 10 2008 053 956.2

(51) Int. Cl. H01L 23/58; H01L 21/66

(52) U.S. Cl. 257/48; 438/18; 257/E21.531; 257/E23.141

(57) ABSTRACT

In a semiconductor device, electrical measurement data may be obtained with enhanced spatial resolution, for instance from within the entire die region, by providing a distributed sensor structure, each of which may be individually accessed by an appropriate interconnect structure, while nevertheless maintaining the required number of terminals and test signals at a low level.

### BACKGROUND OF THE INVENTION

1. Field of the Invention

Generally, the present disclosure relates to the field of fabricating integrated circuits, and, more particularly, to the monitoring characteristics of a metallization system of semiconductor devices on the basis of electrical measurement data.

2. Description of the Related Art

Today's global market forces manufacturers of mass products to offer high quality products at a low price. It is thus important to improve yield and process efficiency to minimize production costs. This holds especially true in the field of semiconductor fabrication, since, here, it is essential to combine cutting-edge technology with mass production techniques. It is, therefore, the goal of semiconductor manufacturers to reduce the consumption of raw materials and consumables while at the same time improve process tool utilization, since, in modern semiconductor facilities, equipment is required which is extremely cost intensive and represents the dominant part of the total production costs. Consequently, high tool utilization, in combination with a high product yield, i.e., with a high ratio of good devices to faulty devices, results in increased profitability.

Integrated circuits are typically manufactured in automated or semi-automated facilities, thereby passing through a large number of process and metrology steps to complete the devices. The number and the type of process steps and metrology steps a semiconductor device has to go through depends on the specifics of the semiconductor device to be fabricated. A usual process flow for an integrated circuit may include a plurality of photolithography steps to image a circuit pattern for a specific device layer into a resist layer, which is subsequently patterned to form a resist mask used in further processes for forming device features in the device layer under consideration by, for example, etch, implantation, deposition, polish and anneal processes and the like. Thus, layer after layer, a plurality of process steps are performed based on a specific lithographic mask set for the various layers of the specified device. For instance, a sophisticated CPU requires several hundred process steps, each of which has to be carried out within specified process margins so as to fulfill the specifications for the device under consideration. Since many of these processes are very critical, a plurality of metrology steps have to be performed to efficiently monitor and control the process flow. Typical metrology processes may include the measurement of layer thickness, the determination of dimensions of critical features, such as the gate length of transistors, the measurement of dopant profiles, the number, the size and the type of defects, electrical characteristics, such as the transistor drive current, the threshold voltage thereof, i.e., the voltage at which a conductive channel forms in the channel region of a field effect transistor, the transconductance, i.e., the change of drive current with gate voltage, and the like.

In a semiconductor facility, a plurality of different product types are usually manufactured at the same time, such as memory chips of different design and storage capacity, CPUs of different design and operating speed and the like, wherein the number of different product types may even reach a hundred and more in production lines for manufacturing ASICs (application specific ICs). Since each of the different product types may require a specific process flow, different mask sets for the lithography, specific settings in the various process tools, such as deposition tools, etch tools, implantation tools, chemical mechanical polishing (CMP) tools, metrology tools and the like, may be necessary. Consequently, a plurality of different tool parameter settings and product types may be encountered simultaneously in a manufacturing environment, thereby also creating a huge amount of measurement data, since, typically, the measurement data are categorized in accordance with the product types, process flow specifics and the like.

Thus, a large number of different process recipes, even for the same type of process tools, may be required, which have to be applied at the process tools at the time the corresponding product types are to be processed in the respective tools. However, the sequence of process recipes performed in process and metrology tools or in functionally combined equipment groups, as well as the recipes themselves, may have to be frequently altered due to fast product changes and highly variable processes involved. As a consequence, the tool performance in terms of throughput and yield are very critical manufacturing parameters as they significantly affect the overall production costs of the individual devices. Therefore, great efforts are made to monitor the process flow in the semiconductor facility with respect to yield-affecting processes or process sequences in order to reduce undue processing of defective devices and to identify flaws in process flows and process tools. For example, at many stages of the production process, inspection steps are implemented for monitoring the status of the devices. Moreover, other measurement data may be generated for controlling various processes, in which the measurement data may be used as feed forward and/or feedback data.

The measurement data for controlling production processes, such as lithography processes and the like, may be obtained by dedicated structures, which may be positioned within the die region if a corresponding area consumption of these structures may be compatible with the overall design criteria of the circuit layout under consideration. In other cases, the test structures may typically be provided in an area outside of the actual die region, which may also be referred to as frame, which may be used for dicing the substrate when separating the individual die regions. During the complex manufacturing sequence for completing semiconductor devices, such as CPUs and the like, an immense amount of measurement data may be created, for instance by inspection tools and the like, due to the large number of complex manufacturing processes, the mutual dependencies of which may be difficult to assess so that usually factory targets may be established for certain processes or sequences, which are assumed to provide process windows to obtain a desired degree of the final electrical behavior of the completed devices. That is, the complex individual processes or related sequences may be monitored and controlled on the basis of respective inline measurement data such that the corresponding process results may be maintained within specified process margins, which in turn may be determined on the basis of the final electrical performance of the product under consideration. Consequently, in view of enhanced overall process control and appropriately targeting the various processes on the basis of the final electrical performance, electrical measurement data may be created on the basis of dedicated test structures that may be provided in the frame region in combination with appropriate probe pads formed in the metallization system at a very advanced manufacturing stage. These electrical test structures may comprise appropriate circuit elements, such as transistors, conductive lines, capacitors and the like, which may be appropriately connected to the probe pads to allow dedicated measurement strategies for assessing electrical performance of the various circuit elements in the test structure, which may then be related to the performance of the circuit elements in the actual die region. These electrical measurement data may include resistance values of conductive structures, threshold voltages of transistors, drive current capability of the transistors, leakage currents and the like, wherein these electrical characteristics may be influenced by the large number of manufacturing processes involved.

In sophisticated semiconductor devices, not only the circuit elements formed in and above a corresponding semiconductor layer may require thorough monitoring, but also the metallization system of the semiconductor device may have a highly complex configuration, thereby also requiring sophisticated process and material monitoring techniques. Due to the ongoing shrinkage of critical dimensions of the semiconductor based circuit features, such as transistors and the like, the device features in the metallization system may also have to be adapted with respect to critical dimensions and electrical performance. For example, due to the increased packing density in the device level, the electrical connections of the circuit elements, such as transistors and the like, may require a plurality of stacked metallization layers, which may include metal lines and corresponding vias, in order to provide the complex wiring regime of the semiconductor device under consideration. The provision of a moderately high number of stacked metallization layers may be associated with a plurality of process-related challenges, thereby requiring efficient monitoring and control strategies. For example, in sophisticated applications, electrical performance of the metallization systems is typically increased by using dielectric materials with a low dielectric constant in combination with metals of high conductivity, such as copper, copper alloys and the like.

Since the manufacturing process for forming metallization systems on the basis of dielectric materials of reduced permittivity, also referred to as low-k dielectrics, and highly conductive metals, such as copper, may include a plurality of highly complex manufacturing steps, the performance of which may depend on the specific material characteristics used for the metallization system, a continuous verification of the process results may be required to monitor the overall electrical performance of the metallization system and also performance of the associated manufacturing processes. For example, the processing of copper material in a semiconductor manufacturing line may require certain specifics with respect to obtaining metal lines and vias due to the specific characteristics of copper in view of material deposition, patterning the same and the like. That is, since copper may not be efficiently deposited on the basis of well-established deposition processes, such as chemical vapor deposition (CVD) and the like, and due to the fact that copper may not form volatile etch byproducts for a plurality of well-established anisotropic etch recipes, typically, a dielectric material is first deposited and patterned to include openings for the metal lines and vias, which are subsequently filled on the basis of a complex deposition regime, which may include the deposition of an appropriate conductive barrier material in combination with the copper bulk material, which may be applied on the basis of electrochemical deposition techniques.

Thereafter, excess material created during the previous deposition sequence has to be removed, which may typically involve, at least at a certain phase, a chemical mechanical polishing or planarization process, thereby obtaining electrically insulated metal lines that are embedded into the dielectric material. As previously indicated, the dimensions of the metal lines may have to be reduced to comply with the increased desired packing density, thereby also requiring reduced spaces between the corresponding metal lines, which in turn may necessitate the usage of low-k dielectric materials in order to maintain parasitic RC (resistance capacitance) time constants at a desired low level, since typically signal propagation delay may mostly be determined by the performance of the metallization system. Thus, a plurality of metallization layers may be stacked on top of each other, which may therefore require sophisticated lithography processes so as to form a corresponding etch mask for patterning the dielectric material of the corresponding metallization layer, followed by a complex deposition regime with a final removal process sequence, during which any excess material may be removed and also the resulting surface topography may be adjusted so as to allow a subsequent sophisticated lithography process for patterning the dielectric material of a subsequent metallization layer. In particular, the process for forming corresponding vias, i.e., contact elements extending from a metal line of one metallization layer to a neighboring metallization layer of the metallization system, may involve a highly critical lithography process in combination with an etch process, while also the subsequent filling in of the conductive material, such as a thin conductive barrier material, possibly in combination with a seed material, may represent critical process steps and may thus have a significant influence on the overall electrical performance of the metallization layer under consideration. Furthermore, many of these complex manufacturing processes, such as lithography, etching, polishing and the like, may depend on the “local” neighborhood of the die region of interest in terms of the resulting process output. That is, etch behavior, deposition behavior, polishing behavior and the like may locally depend on the degree of patterning in the local neighborhood so that certain process variations may occur with respect to device areas having a different “pattern density.” For example, the removal rate of device areas having a moderately low pattern density, i.e., the number of device features, such as trenches, vias, gate electrodes and the like per unit area, may differ from the removal rate in areas of increased pattern density, such as functional areas of sophisticated semiconductor devices in which, for instance, a high density of circuit elements, such as transistors and the like, and thus also of corresponding metal lines and vias, may be encountered. For this reason, the height level may differ between a device region of high pattern density compared to a device region of moderately low pattern density, thereby also resulting in a different performance of associated lithography processes that are carried out to define critical features sizes in the various device areas. Since the lithography process may represent the basis for obtaining critical dimensions of device features, such as transistors, metal lines and the like, a corresponding difference in the critical dimensions and thus the overall performance of these device features may occur. This holds especially true for dedicated test structures that may be formed in the frame region of the semiconductor devices. Consequently, in sophisticated semiconductor devices, corresponding test structures positioned in the frame area of the semiconductor devices may exhibit an increased discrepancy with respect to subtle characteristics, such as critical dimensions, material composition and the like, which may also result in a corresponding difference in electrical performance. Consequently, if manufacturing processes and materials are evaluated on the basis of test structures positioned in the frame region of the semiconductor devices, the degree of authenticity of measurement data obtained from these test structures may be reduced and therefore these test structures may not properly represent the actual electrical performance of circuit elements, which may thus result in an inappropriate targeting of complex manufacturing processes, such as lithography steps and the like, thereby finally resulting in a deteriorated yield distribution, since, increasingly, products of inferior quality may be produced.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to semiconductor devices and methods in which electrical measurement data may be obtained with increased correlation with respect to electrical performance of circuit elements of the active circuitry, such as transistors, resistors and metal features in the metallization system, by providing a “spatially distributed” test structure or sensor structure, which may be appropriately interconnected by an interconnect structure in such a manner that electrical access of the spatially distributed sensor structure may be accomplished with a moderately low degree of input/output capabilities. Furthermore, the spatially distributed configuration of the sensor structure may enable detection of material characteristics, process performance and the like on the basis of electrical measurement data with a high spatial resolution so as to identify a spatial dependency of quality criteria, which in turn are correlated to corresponding manufacturing processes and materials used in sophisticated semiconductor devices. In some illustrative aspects disclosed herein, the spatially distributed sensor structure may be provided within a die area of the semiconductor device so that die internal electrical measurement data may be obtained that may provide a high degree of authenticity with respect to device features of functional die areas, while additionally the spatial distribution of the corresponding sensor structure may enable the monitoring of performance of material and processes at critical die regions, such as die corners, edges of the die, specific structures and the like. Thus, based on corresponding interconnect structures, each individual sensor cell, which in turn may also comprise one or more sensor elements of the same or different configuration, may be electrically accessed, thereby providing the desired spatial resolution of the obtained electrical measurement data, while also providing the possibility of reducing I/O capabilities, for instance by connecting the individual sensor cells in an array-like manner.

In some illustrative aspects disclosed herein, the spatially distributed sensor structure may comprise specifically designed sensor elements in the individual sensor cells to identify the quality of device features of the metallization system, for instance performance of vias, the presence of cracks within the metallization systems which may frequently occur due to the usage of highly sensitive low-k and ultra low-k (ULK) dielectric materials and the like. Consequently, a high degree of flexibility in selecting appropriate positions for the individual sensor cells may be accomplished so that very similar conditions during the fabrication of these sensor cells with respect to adjacent functional die areas may be established, thereby resulting in high correlation between the electrical performance of the corresponding sensor cells and the neighboring functional areas.

One illustrative semiconductor device disclosed herein comprises a plurality of functional die areas formed above a substrate of a die, wherein each of the functional die areas comprises circuit elements formed in a semiconductor layer. The semiconductor device further comprises a plurality of sensor die areas distributed across the die at intermediate locations with respect to the functional die areas, wherein each of the plurality of the sensor die areas comprises a first electrical sensor element. Additionally, the semiconductor device comprises a sensor interconnect structure formed in a metallization system of the semiconductor device, wherein the sensor interconnect structure electrically connects the plurality of sensor die areas.

A further illustrative semiconductor device disclosed herein comprises a metallization system formed in a die region and comprising a plurality of stacked metallization layers. The semiconductor device further comprises a plurality of electrical sensor cells formed in two or more of the metallization layers of the metallization system, wherein at least some of the plurality of sensor cells are laterally separated by functional areas of the semiconductor device. Additionally, the semiconductor device comprises a sensor interconnect structure formed in the metallization system and electrically connecting the plurality of sensor cells.

One illustrative method disclosed herein relates to the monitoring of spatial variations of at least one quality criterion of a semiconductor device. The method comprises providing a plurality of electric sensor cells in a spatially distributed manner within a locally restricted area above a substrate of the semiconductor device, wherein the locally restricted area comprises functional areas comprising dummy circuit elements and/or functional circuit elements. Furthermore, the method comprises electrically accessing the sensor cells via a sensor interconnect structure that is formed at least partially in a metallization system of the semiconductor device so as to obtain an individual electric response from each of the sensor cells. Finally, the method comprises evaluating a spatial variation of the at least one quality criterion of the semiconductor device on the basis of the individual electric responses.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a top view of a locally restricted area of a semiconductor device, such as a die, in which a plurality of sensor cells may be spatially distributed among functional die areas, wherein a corresponding interconnect structure enables individual electrical access of the sensor cells to obtain electrical measurement data in a spatially distributed manner, according to illustrative embodiments;

FIG. 1b schematically illustrates a wiring scheme provided by the sensor interconnect structure, wherein an array-like interconnection may allow individual electrical access without unduly increasing I/O capabilities of the corresponding semiconductor device, according to illustrative embodiments;

FIG. 1c schematically illustrates a cross-sectional view of a portion of one sensor cell, in which a corresponding sensor element may extend to and into the semiconductor layer, according to illustrative embodiments;

FIG. 1d schematically illustrates a cross-sectional view of a portion of an individual sensor cell in which sensor elements of different configuration may be provided within the metallization system so as to enable the detection of failures, wherein the position of the sensor cell may provide the lateral position information, while the configuration of the sensor elements may provide vertical position information with respect to a performance quality criterion, according to illustrative embodiments;

FIG. 1e schematically illustrates a cross-sectional view of a portion of an individual sensor cell, in which a plurality of sensor elements of the same type may be connected to each other in order to enhance overall “sensitivity” of the sensor cell, according to still further illustrative embodiments; and

FIG. 1f schematically illustrates a top view of a plurality of sensor cells, each of which may include a plurality of different types of sensor elements, wherein each type is represented by a plurality of individual sensor elements, according to further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure provides semiconductor devices and methods in which the correlation between electrical measurement data and the electrical performance of circuit elements, such as transistors, metal features and the like, within the die region may be enhanced. For this purpose, electrical measurement data may be obtained on the basis of a spatially distributed test structure or sensor structure in which individual sensor cells may be appropriately interconnected with each other in order to allow electrical access without undue complexity of a corresponding I/O (input/output) structure. Consequently, the configuration of the individual sensor cells may be appropriately adjusted to the requirements with respect to obtaining meaningful measurement data and also with respect to the overall circuit layout. That is, the size of the sensor cells, the number of individual sensor elements formed therein, as well as the variety of different types of sensor elements in each of the sensor cells, may be selected in accordance with overall requirements to appropriately position a sensor cell at a desired position, for instance in the vicinity of functional circuit or die areas, in order to obtain a highly correlated measurement data set with respect to the adjacent functional die area. On the other hand, the overall configuration of the individual sensor cells may be selected such that significant redesign efforts of the actual functional die areas may not be required. In other illustrative embodiments, the local neighborhood of a sensor cell may be appropriately brought into conformity with the conditions of actual device areas by providing corresponding dummy circuit features in order to “simulate” the corresponding pattern density with a high degree of authenticity with respect to the actual circuit areas under consideration. In still other embodiments, additional “non-functional” circuitry may be added to at least some of the sensor cells, which may not be required for the actual operation of the semiconductor device under consideration, which, however, may be used in obtaining appropriate electrical measurement data, for instance by providing switches for temporarily adjusting the connection status of a corresponding sensor cell by heating or cooling the corresponding sensor cell and the like. For instance, respective transistor elements may be included into the sensor cell in order to provide corresponding switches, possibly in combination with a corresponding control circuitry, in order to reconfigure arrangement of corresponding sensor elements, such as contact elements, metal features and the like. In other cases, at least some of these transistor devices may represent elements when quality criteria of circuit elements within the device level are to be estimated. In other cases, the provision of heating and/or cooling elements within the sensor cells may provide the possibility of establishing specified “environmental” conditions in a highly locally restricted manner, thereby enabling the “simulation” of hot spots and the like, thereby even further enhancing the authenticity of the corresponding electrical measurement data with respect to actual circuit areas.

In some illustrative embodiments disclosed herein, quality criteria of sophisticated metallization systems, for instance with respect to detecting cracks, delaminations or any other weaknesses in the metallization system, may be evaluated, for instance, by providing different types of sensor elements in the form of stacked via chains and the like, wherein the lateral position information of a corresponding quality criterion may be obtained on the basis of the actual position of the individual sensor cell, while a “vertical” identification of a corresponding failure, such as a crack in the sensitive dielectric layer stack and the like, may also be achieved.

The individual sensor cells may be designed on the basis of well-established structural components, wherein, however, the positioning of the individual sensor cells in combination with the interconnect structure provides the possibility of obtaining a desired spatial resolution with respect to one or more quality criteria. For example, in critical device areas, an increased density of sensor cells may be provided to obtain enhanced spatial coverage, while, in less critical device regions, a reduced number of sensor cells may be positioned. Furthermore, within individual sensor cells, the same type of basic sensor elements may be provided with a desired high number so as to obtain an increase of overall sensitivity with respect to a quality criterion that may be detected based on this specific type of sensor element, wherein, however, the size of each individual sensor cell may be selected on the basis of the number of sensor elements of each type to further enhance overall flexibility in appropriately distributing the sensor cells across a locally restricted device area, for instance across the entire die of the semiconductor device.

It should be appreciated that the principles disclosed herein may be advantageously applied to obtain die internal measurement data from actual product die, thereby providing a high degree of authenticity of the corresponding measurement data. In other cases, the distributed sensor structure may also be used in dedicated test chips, wherein an even further increased number of sensor cells may be provided to enhance the overall spatial resolution of the electrical measurement data obtained. Moreover, based on the corresponding test chips, the power cycling may be efficiently simulated so as to obtain corresponding electrical measurement data with a high spatial resolution. In other cases, the concept of a spatial distribution of individual sensor cells using an appropriate interconnect structure may also be applied to test structures formed in the frame region of semiconductor devices, for instance with respect to development and qualification of new technologies or process modifications, wherein, advantageously, corresponding dummy features may be provided to increase overall authenticity of the electrical measurement data, while the interconnect structure may be configured such that a reduced I/O capability may be required for the corresponding test structures.

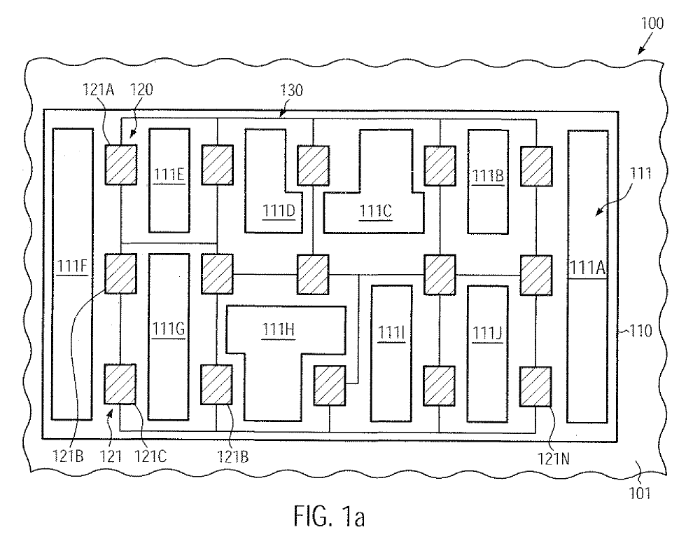

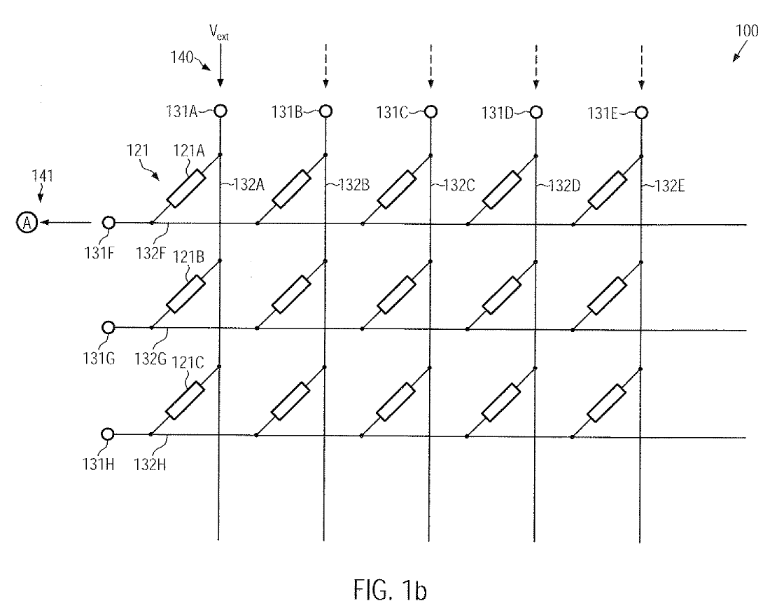

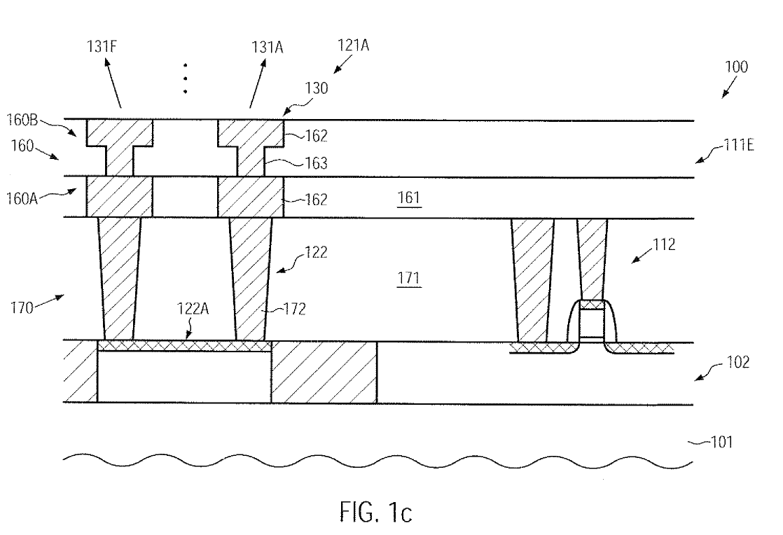

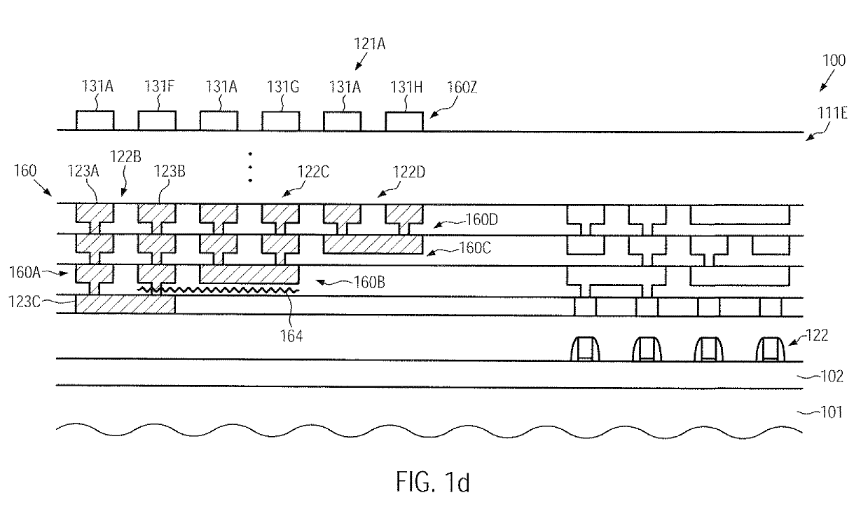

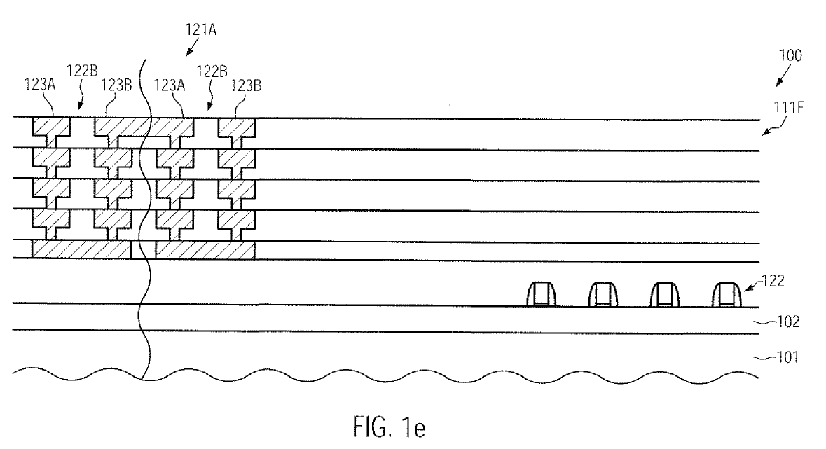

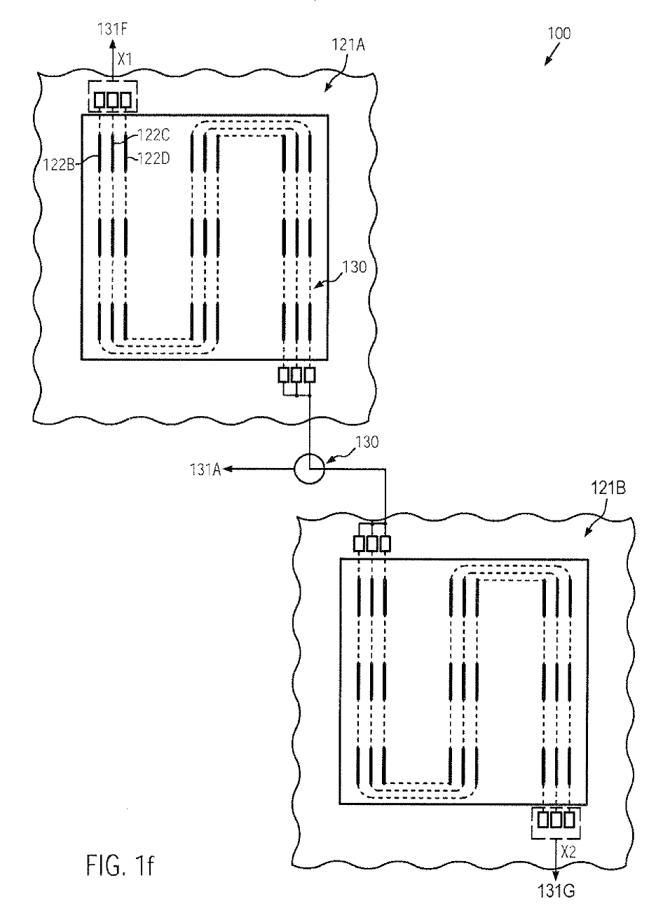

FIG. 1a schematically illustrates a top view of a semiconductor device 100 comprising a substrate 101, such as a semiconductor substrate, an insulating substrate or generally any appropriate carrier material for forming thereon and thereabove circuit elements, such as transistors, capacitors, resistors, metal lines, vias and the like, as is typically required for sophisticated semiconductor devices. Furthermore, the semiconductor device 100 comprises a locally restricted area 110, which, in one illustrative embodiment, may represent a die of the semiconductor device 100. In this case, the die 110 may be provided together with a plurality of other die (not shown) on the basis of the substrate 101, for instance in the form of a wafer, while in other cases the die 110 may be separated from neighboring die, depending on the overall process strategy. The locally restricted semiconductor region or die 110 may comprise, in the embodiment shown, a plurality of functional areas 111, which may also be referred to as areas 111A, 111B, 111C, 111D, 111E, 111F, 111G, 111H, 111I, 111J, when appropriate. The functional areas 111 may be understood as device areas of the device 100 in which “functional” circuit elements may be provided in accordance with a specific circuit layout in order to obtain a desired circuit function. That is, the functional areas 111 may represent circuit portions, such as digital circuitry and analog circuitry, depending on the specific architecture and configuration of the semiconductor device 100 under consideration. It should be appreciated that at least some of the functional areas 111 may differ in pattern density, type of circuit elements and the like, as is also previously discussed, so that an influence of even subtle process variations with respect to overall device performance may be different in these functional areas 111. Furthermore, generally, the process result of sophisticated manufacturing processes, such as lithography processes, etch processes and the like, may depend on the position of a corresponding functional area 111 within the die 110. For example, frequently, a systematic deviation of process outputs and thus of characteristics of device features may be observed that may depend on the lateral location of a corresponding circuit feature within the die 110. For instance, the etch behavior or deposition behavior at the edge of the die 110 may differ from a corresponding behavior in the center of the die 110, thereby resulting in a corresponding variation of device characteristics.

Furthermore, the semiconductor device 100 as shown in FIG. 1a may further comprise a distributed test or sensor structure 120, which may comprise a plurality of individual sensor cells 121A, 121B, 121C . . . 121N, which may also be commonly referred to as sensor cells 121, if appropriate. A sensor cell may be understood as a locally restricted area within the die 110, which may include at least one sensor element (not shown), which may be configured so as to be electrically accessed and to provide measurement data for evaluating at least one quality criterion. For example, a quality criterion may represent a resistance value, a voltage value, a current value or any other electrically measurable parameter, such as a frequency, capacitance and the like, which may be correlated to the actual electrical performance of the sensor element. As will be explained later on in more detail, each of the sensor cells 121 may be considered an entity in the sense that each of the cells 121 may be electrically accessed to obtain measurement data related to a lateral position of the corresponding cell 121 within the die 110. For this purpose, the semiconductor device 100 may comprise an appropriate interconnect structure 130, which may also be referred to as a sensor interconnect structure, and which may be configured to electrically connect the individual sensor cells 121 to enable electrical access of each of the cells 121. In some illustrative embodiments, the interconnect structure 130 may be configured so as to connect the individual sensor cells 121 such that individual electrical access may be accomplished on the basis of a number of I/O pins that is significantly less compared to the number of sensor cells 121. It should be appreciated that the interconnect structure 130 is illustrated in a very schematic manner in order to not unduly obscure the basic principle wherein, however, a respective number of interconnect components, such as metal lines, vias and the like, may be provided in a corresponding metallization system (not shown) of the device 100 in order to obtain the desired overall wiring architecture of the structure 130. It should also be appreciated that the interconnect structure 130 may also provide the desired mutual electrical connection of respective sensor elements within each individual sensor cell 121, as will be described in more detail later on. Additionally, if required, the interconnect structure 130 may comprise any wiring regimes that may be required for operating any additional circuitry, such as heating and/or cooling elements (not shown), controlling switching elements, such as transistors, supplying corresponding control circuitry that may be individually provided in each of the sensor cells 121 and the like.

On forming the semiconductor device 100 as shown in FIG. 1a, the size, configuration and lateral position of each of the sensor cells 121 may be determined in accordance with requirements for obtaining electrical measurement data from within the restricted device area 110. For instance, as previously discussed, the sensor cells 121 may be designed on the basis of well-established device features, wherein a corresponding number and type of device features may be combined so as to obtain the individual sensor cells 121, which, however, may differ in their configuration, depending on the overall requirements. Furthermore, the local neighborhood of the sensor cells 121 may be selected so as to obtain the desired high degree of authenticity of the corresponding electrical measurement data, for instance, by appropriately positioning the sensor cells 121 between intermediate functional areas, such as the areas 111, wherein, in some illustrative embodiments, additionally, further device features may be positioned in the vicinity of one or more of the sensor cells 121 in order to obtain the desired environment during the subsequent manufacturing processes. Depending on the number, the lateral position and the configuration of the individual sensor cells 121, the interconnect structure 130 may be designed so as to obtain the distributed interconnected sensor structure 120, in which individual access to each of the cells 121 may be accomplished on the basis of a low number of corresponding pins that may be accessible by external test equipment.

FIG. 1b schematically illustrates a schematic configuration of the individual sensor cells 121 in combination with an electrical configuration of the interconnect structure 130. As illustrated, the individual sensor cells 121 may be represented by “resistors,” wherein it should be understood that this representation is of illustrative nature only and each of the sensor cells 121 may have any configuration as required for obtaining the desired electrical measurement data. That is, the “resistors” as illustrated in FIG. 1b representing the sensor cells 121 may be comprised of a plurality of individual sensor elements of the same or different types, which may actually require a higher number of interconnect lines than as illustrated in FIG. 1b. In other cases, the sensor cells 121 may comprise a respective switching structure for temporarily connecting respective ones of the individual sensor elements to the interconnect structure 130, thereby reducing the complexity of the interconnect structure 130. As illustrated, the interconnect structure 130 may comprise interconnecting components 132A, 132B, 132C, 132D, 132E, 132F, 132G, 132H which may represent respective components in various metallization layers of a metallization system of the device 100, for instance in the form of metal lines and vias, to establish the corresponding electrical connection. For example, the electrical connections 132A, 132B, 132C, 132D, 132E may finally connect to corresponding I/O pins 131A, 131B, 131C, 131D, 131E which may be configured to allow access by external test equipment, as indicated by 140. For instance, the I/O components 131A, 131B, 131C, 131D, 131E may be connectible to an external voltage source on the basis of well-established electrical probes. Similarly, the connections 132F, 132G, 132H may connect to corresponding I/O components, such as probe pads, I/O pins and the like 131F, 131G, 131H which may also allow contact to external test equipment 141 so as to detect an electrical response of each of the sensor cells 121. For example, as is indicated in FIG. 1b, the current flowing through each of the sensor cells 121 may be determined in order to obtain a corresponding resistance value, which may be used for evaluating one or more quality criteria of the sensor cell 121 under consideration. For example, a quality criterion, such as the status of a dielectric material, the conductivity of a via structure, the conductivity of doped regions and the like, may be evaluated on the basis of the electrical measurement data obtained on the basis of the external test equipment 140, 141 individually for each of the sensor cells 121. In the arrangement shown in FIG. 1b, the interconnect structure 130 may define an array-like configuration of the sensor cells 121, wherein a plurality of sensor cells 121 are connected with one “terminal” to the same connection, such as the connections 131A, 131B, 131C, 131D, 131E, thereby enabling the simultaneous contact of a plurality of subsets of the sensor cells 121 with the external test equipment 140, for instance provided in the form of a voltage source. For example, the sensor cells 121A, 121B and 121C may be simultaneously connected with a voltage source upon contacting the connection 131A with the external equipment 140. On the other hand, the remaining terminals 131B, 131C, 131D, 131E may remain non-connected so that, upon connecting the connection 131F with a dedicated test equipment 141, the response of the sensor cell 121A may be individually obtained for evaluating the respective quality criterion according to the position corresponding to the sensor cell 121A (see FIG. 1a). Similarly, the electrical responses of the sensor cells 121B, 121C may be obtained, simultaneously or sequentially, depending on the capability of the test equipment 141. Consequently, the individual sensor cells 121 may be “read out” while at the same time maintaining the number of required terminals 131A, 131B, 131C, 131D, 131E, 131F, 131G, 131H at a moderately low number. Furthermore, spatially resolved electrical measurement data may be obtained as soon as the corresponding terminals 131A, 131B, 131C, 131D, 131E, 131F, 131G, 131H are accessible by the external test equipment 140, 141. For instance, after completing the corresponding metallization system of the device 100, such as providing the corresponding bump structure in sophisticated semiconductor devices in which connection to external packing materials or carrier materials may be established by bump structure, or after providing the corresponding bond pads, the electrical test measurements may be performed on a wafer basis, thereby providing a high degree of overall test efficiency. In other cases, the measurement data may be obtained after dicing the substrates, thereby also enabling the assessment of any influences caused by these additional process steps. In still other cases, when the corresponding number of I/O pins is available in the final package of the semiconductor device 100, the corresponding electrical measurement data may also be obtained after packaging of the device 100. For example, in view of reducing the overall delay of providing electrical measurement data, respective measurements may be performed immediately after the terminals 131A, 131B, 131C, 131D, 131E, 131F, 131G, 131H are accessible by the external test equipment 140, 141.

FIG. 1c schematically illustrates a cross-sectional view of the semiconductor device 100, wherein a portion of the sensor cell 121A is shown. The semiconductor device 100 may comprise a semiconductor layer 102, in and above which corresponding circuit elements 112 may be formed, for instance in an adjacent die area, such as the area 111E (see FIG. 1a). In other cases, the circuit elements 112 may represent corresponding dummy circuit elements, if an appropriate environment for the sensor cell 121A may be required to enhance the authenticity of the corresponding electrical measurement data, as previously discussed. Moreover, in the embodiment shown, the sensor cell 121A may comprise a sensor element 122 which is to be understood as any device feature which may, upon being accessed by external test equipment, produce an electrical signal that allows evaluation of at least one quality criterion. In the embodiment shown, the sensor element 122 may comprise at least a portion 122A that is formed within the semiconductor layer 102. For instance, the portion 122A may comprise doped semiconductor material, metal-containing materials, as are typically used for enhancing conductivity of semiconductor materials, for instance in the form of metal silicides and the like. For example, the portion 122A may be formed in accordance with process strategies as may also be used during the formation of the circuit elements 112, thereby enabling an evaluation of one or more quality criteria with respect to the circuit elements 112. Moreover, the semiconductor device 100 may comprise a contact structure 170, which may be comprised of a dielectric material 171 in combination with corresponding contact elements 172. Moreover, a metallization system 160 may be formed above the contact structure 170 so as to appropriately interconnect the circuit elements 112 in the corresponding functional area 111E, while also comprising the interconnect structure 130 so as to appropriately connect the sensor cell 121A and thus the sensor element 122 with the remaining sensor cells 121 (see FIG. 1a). The metallization system 160 may comprise a plurality of metallization layers 160A, 160B, depending on the overall complexity of the semiconductor device 100. The metallization layers 160A, 160B may comprise corresponding metal lines 162 and/or vias 163, which may vertically connect respective metal lines 162 of neighboring metallization layers, such as the layers 160A, 160B. The corresponding vias 163 and metal lines 162 may be embedded in a dielectric material, which may typically comprise sensitive dielectric materials, such as low-k dielectrics, ULK materials and the like in sophisticated applications, as previously explained. Depending on the specific configuration of the sensor cell 121A and thus of the sensor element 122, the various components of the metallization system 160 may be formed so as to establish corresponding components of the interconnect structure 130 in order to reliably connect to the portion 122A to obtain information on the portion 122A. That is, if the portion 122A, possibly in combination with components of the contact structure 170, is the actual object of interest, the remaining components in the metallization system 160 may be formed on the basis of design rules so as to provide a high degree of reliability even for a moderately wide range of process fluctuations. In this case, corresponding process variations concerning the metallization system 160 may have a negligible influence on the overall electrical response of the sensor cell 121A, which thus allows evaluation of the portion 122A, possibly in combination with the contact structure 170, which also represents a highly critical device portion. In other cases, the components of the metallization system 160 may represent the actual object of interest and thus may represent the sensor element 122 of interest so that the portion 122A may be formed with relaxed constraints in order to provide a reliable connection between the components of the element 122 provided in the metallization system 160. Hence, any failure of these components within the metallization system 160 may result in a deteriorated electrical performance of the overall element 122, or even a total failure, such as a discontinuation of the conductive path wherein, due to the relaxed process conditions for forming the portion 122A, failure of the portion 122A may be excluded, thereby indicating a failure in the metallization system 160. As will be described later on in more detail, in other illustrative embodiments, positional information with respect to the vertical position within the metallization system 160 may also be obtained on the basis of appropriately designed sensor cells 121.

The semiconductor device 100 as shown in FIG. 1c may be formed on the basis of well-established process techniques, for instance for forming the circuit elements 112 and the portion 122A in accordance with corresponding design rules and process techniques. Thereafter, the contact structure 170 and the metallization system 160 may be formed on the basis of a corresponding manufacturing sequence, wherein local variations of resulting device features across the substrate 101 also may be reflected in the corresponding features of the sensor cell 121A, as previously described. Thus, after completing the metallization system 160, which may require the formation of a plurality of metallization layers, thereby also completing the interconnect structure 130, the sensor cell 121A can be electrically accessed, for instance by accessing the sensor element 122 on the basis of the corresponding terminals 131A, 131F. For instance, by connecting the terminals 131A, 131F with an external voltage source and current measurement device, the overall resistance of the sensor element 122 may be determined and may be used for evaluating one or more quality criteria of the sensor element 122 and thus of the circuit elements 112 or any respective device features provided in the metallization system 160 for interconnecting the circuit elements 112, for example, the sensor element 122 may be tested with respect to an open circuit in order to identify a total failure within the metallization system 160. In other cases, corresponding resistance values may be correlated with a desired electrical performance of the sensor element 122 and thus of the circuit elements 112 on the basis of a predetermined correlation.

FIG. 1d schematically illustrates the semiconductor device 100 according to further illustrative embodiments in which at least some of the sensor cells, such as the sensor cell 121A, may comprise a plurality of sensor elements 122B, 122C, 122D so as to determine a local failure in one of the individual metallization layers 160A, 160B, 160C, 160D. As illustrated, the individual sensor elements 122B, 122C, 122D may extend, starting from a given metallization layer 160D, into different depths and thus into different metallization layers of the system 160. For example, if the metallization layers 160D to 160A are the subject of interest with respect to determining failures in critical vias or to detect cracks and delamination failures in corresponding metallization layers, the sensor elements 122B, 122C, 122D may be provided such that a high degree of authenticity with actual device features of the metallization system 160 in the functional areas of interest, such as the area 111E, is achieved while any additional metal components of the metallization system 160 may be provided with non-critical design rules in order to reduce the probability of creating failures for connecting the sensor elements 122B, 122C, 122D with the respective terminals 131A, 131F that may be connected to the external test equipment, as previously explained. In other illustrative embodiments the sensor elements 122B, 122C, 122D may extend across the entire depth of the metallization system 160. For instance, the elements 122B, 122C, 122D are provided as stacked via chains 123A, 123B which are electrically connected by a metal line 123C provided in the corresponding metallization layer to which the respective via chains 123A, 123B of the associated sensor elements 122B, 122C, 122D extend. As illustrated, the stacked via chains 123A, 123B of the sensor element 122B may extend down to the very first metallization layer 160A, in which these stacked via chains are connected by the corresponding metal line 123C. On the other hand, the via chains 123A, 123B of the sensor element 122C may extend to the next higher metallization layer 160B, in which the corresponding connecting metal region 123C is provided, while for the sensor element 122D, the “via chains” 123A, 123B may terminate in the metal region 160C.

After completing the device 100, one or more quality criteria of the device 100 and thus of the metallization system 160, for instance with respect to the metallization layers 160A, 160B, 160C, 160D, may be evaluated on the basis of the sensor cell 121A with respect to a position corresponding to the sensor cell 121A by appropriately connecting the sensor elements 122B, 122C, 122D with external test equipment. For example, if critical via processes are to be evaluated on the basis of the sensor cell 121A, a failure of the corresponding via in the metallization layer 160B may be detected by obtaining a moderately high resistance value or an open circuit, while all other sensor elements, such as the elements 122C, 122D provide the expected electrical behavior. In other cases, the sensor cell 121A may be provided so as to estimate the metallization system 160 and thus the correlated manufacturing techniques with respect to the formation of any cracks 164, which may typically occur in sophisticated metallization systems, as previously explained. In this case, if desired, the via chains 123A, 123B may be formed on the basis of less critical process constraints, for instance by using less critical lateral dimensions of the corresponding via chains 123A, 123B in order to provide a low probability of creating non-crack related via failure. If, therefore, a failure in the sensor element 122B is detected, while the remaining sensor elements 122C, 122D exhibit an expected electrical performance, the vertical position of the crack 164 may be determined to be below the metallization layer 160C. Consequently, by providing different types of sensor elements, such as the elements 122B, 122C, 122D, a position information with respect to error-prone device features in the vertical direction may also be obtained, while the lateral position of the sensor cell 121A with respect to the die 110 (see FIG. 1a) may provide the desired lateral spatial resolution.

FIG. 1e schematically illustrates a cross-sectional view of the semiconductor device 100 in which at least some of the sensor cells 121, such as the sensor cell 121A, may comprise a plurality of sensor elements, such as the elements 122B, which may be appropriately connected in order to enhance the overall “sensitivity” of the sensor cell 121A with respect to a certain quality criterion. For example, the stacked via chains of the plurality of sensor elements 122B may be connected in series to enhance the “area” coverage of the sensor cell 121A, thereby increasing the probability of detecting a corresponding crack or any other failure in the metallization system that may occur in the area of the sensor cell 121A. It should be appreciated that, although two sensor elements 122B are illustrated in FIG. 1e, any number of sensor elements of identical configuration may be connected in order to increase sensitivity. It should further be appreciated that other types of sensor elements may also be provided in an appropriate number so as to increase the sensitivity of the other types of sensor elements. It should further be appreciated that, in other cases, a parallel connection of the corresponding sensor elements may be used, if appropriate. For example, if the respective sensor elements may comprise test structures of open circuit, for instance for testing reliability of a dielectric material, corresponding structures may be connected in parallel so that failure of a dielectric material in one of these structures may be detected by simultaneously accessing a plurality of these test structures.

FIG. 1f schematically illustrates a top view of the semiconductor device 100 according to illustrative embodiments, in which at least some of the sensor cells 121, such as the cells 121A, 121B, may comprise different types of sensor elements wherein a plurality of individual sensor elements may be provided for each type of sensor element. For instance, the sensor cells 121A, 121B may comprise the sensor elements 122B, 122C and 122D (also see FIG. 1d), which may be distributed across the area of the corresponding sensor cell 121A. For this purpose, each type of sensor element may comprise a plurality of individual members which are electrically connected in series by means of an appropriate configuration of the interconnect structure 130. Thus, a failure in one of the plurality of sensor elements 122B may thus result in a corresponding failure of the entire series connection of the sensor elements 122B. The same holds true for the corresponding plurality of sensor elements 122C and 122D, respectively. Furthermore, the interconnect structure 130 may further be configured to separately connect the serially connected elements 122B, 122D, 122C with respective terminals 131F so that, for each type of sensor element, a separate terminal 131F may be available. On the other hand, at the other end of the serially connected elements 122B, 122C and 122D, a common conductive path may be provided by the interconnect structure 130 so as to connect to a common terminal 131A. Similarly, the sensor cell 12Bb may be connected to the common terminal 131A, while separate respective terminals 131G may be provided for each of the corresponding serially connected sensor elements 122B, 122D and 122C of the cell 121B. In this manner, the overall area coverage in each of the sensor cells 121A, 121B may be enhanced by appropriately connecting sensor elements belonging to the same type while nevertheless not unduly contributing to increased complexity of the interconnect structure 130 and the corresponding terminals that provide external access by test equipment. It should be appreciated that the spatial distribution of the sensor elements 122B, 122C, 122D within the individual sensor cells 121A, 121B is of illustrative nature only and that any other appropriate spatial coverage may be selected. Furthermore, any number of different types of sensor elements may be used, for instance for covering a larger number of stacked metallization layers, providing test structures for evaluating quality criteria of circuit elements formed in and above the semiconductor layer, as previously discussed, and the like. Thus, by “clustering” sensor elements, such as via chains, within one sensor cell, a high degree of area coverage may be obtained, while the provision of different types of sensor elements may also enable identification of different device layers, such as metallization layers, that may suffer from process dependent failures. Furthermore, a corresponding clustering of one or more types of sensor elements may be used in relation to specific positions of the sensor cells so that, for instance, highly critical die regions may be “sampled” with increased reliability and resolution. For example, proximity to die corners, edges or specific structures may be taken into consideration by appropriately adapting the overall density of test elements, while a coarse coverage of the entire die region may be achieved on the basis of appropriately positioning corresponding sensor cells.

As a result, the principles disclosed herein relate to semiconductor devices and methods in which single sensor cells may be provided to obtain a spatially distributed sensor structure, wherein each individual sensor cell may be separately accessed by external test equipment to obtain a spatially resolved electrical measurement data. The sensor cells may be comprised of any appropriate structures, such as device features formed in the semiconductor layer, in the contact structure, in the metallization layer and the like, so that lateral and vertical spatial evaluation of quality criteria may be enabled. In some illustrative embodiments, the distributed sensor structure may be provided in product die so as to obtain die internal measurement data wherein the spatial resolution may be readily adapted to die specific aspect by appropriately adapting a local density of respective sensor elements. In other cases, dedicated test chips may be used for obtaining an increased spatial resolution within the die region, since nearly the entire test chip area may be used for forming an area of corresponding sensor cells. Also, specific test structures in the frame region of semiconductor devices may be provided in the form of distributed sensor cells, wherein appropriate die internal conditions may also be established by providing respective dummy circuit features. Based on the distributed sensor structure, electrical measurement data may be obtained after completing the metallization system prior to actually packaging the semiconductor devices, thereby providing a reduced delay of delivering the electrical measurement data. In other cases, depending on the I/O capabilities of the corresponding package, the electrical measurement data may be obtained after packaging with high spatial resolution.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed is:

1. A semiconductor device, comprising:
a plurality of functional die areas formed above a substrate of a die, each of said functional die areas comprising circuit elements formed in a semiconductor layer;
a plurality of sensor die areas distributed across said die at intermediate locations with respect to said functional die areas, each of said plurality of sensor die areas comprising a first electrical sensor element; and
a sensor interconnect structure formed in a metallization system of said semiconductor device, said sensor interconnect structure electrically connecting said plurality of sensor die areas.

2. The semiconductor device of claim 1, wherein said first sensor element comprises a first type of stacked via chains formed in two or more stacked metallization layers of said metallization system.

3. The semiconductor device of claim 2, wherein at least some of said plurality of sensor die areas further comprise a second sensor element that comprises a second type of stacked via chains formed in said two or more metallization layers and at least one further metallization layer.

4. The semiconductor device of claim 3, wherein said second type of stacked via chains extends to and terminates in a first metallization layer that is formed above said semiconductor layer.

5. The semiconductor device of claim 3, wherein said second type of stacked via chains is connected to said semiconductor layer via a contact structure.

6. The semiconductor device of claim 3, wherein one or more of said at least some sensor die regions comprise at least one further type of stacked via chains and wherein said at least one further type of stacked via chains differs from said first and second types of stacked via chains.

7. The semiconductor device of claim 1, wherein said first sensor element of at least some of said sensor die areas comprises a circuit element formed in said semiconductor layer.

8. The semiconductor device of claim 1, further comprising a second electrical sensor element in each of said sensor die regions, wherein said second sensor element has a different configuration compared to said first sensor element.

9. The semiconductor device of claim 1, wherein each of said plurality of sensor die areas comprises a plurality of further sensor elements having the same configuration that are electrically connected in series.

10. The semiconductor device of claim 1, wherein said sensor interconnect structure is configured to provide electric access individually to each of said plurality of sensor die areas.

11. The semiconductor device of claim 10, wherein said sensor interconnect structure is configured to interconnect said plurality of sensor die areas in an array form, in which different subsets of said sensor die areas are controllably connectable to a shared voltage source.

12. A semiconductor device, comprising:
a metallization system formed in a die region and comprising a plurality of stacked metallization layers;
a plurality of electrical sensor cells formed in two or more of said metallization layers of said metallization system, at least some of said plurality of sensor cells being laterally separated by functional areas of said semiconductor device; and
a sensor interconnect structure formed in said metallization system and electrically connecting said plurality of sensor cells.

13. The semiconductor device of claim 12, wherein each of said plurality of sensor cells comprises a first electrical sensor element and a second electrical sensor element, wherein said first and second electrical sensor elements have different configurations.

14. The semiconductor device of claim 12, wherein each of said plurality of sensor cells comprises stacked via chains.

15. The semiconductor device of claim 14, wherein each of said plurality of sensor cells comprises a first type of stacked via chains and a second type of stacked via chains, wherein said first and second types of stacked via chains extend across a different number of stacked metallization layers.

16. The semiconductor device of claim 13, wherein said sensor interconnect structure comprises a first interconnect portion and a second interconnect portion, wherein said first interconnect potion is configured to serially connect said first sensor elements of said plurality of sensor cells and said second interconnect portion is configured to serially connect said second sensor elements of said plurality of sensor cells.

17. The semiconductor device of claim 13, wherein each of said sensor cells comprises a plurality of said first sensor elements and a plurality of said second sensor elements.

18. A method of monitoring spatial variations of at least one quality criterion of a semiconductor device, the method comprising:
providing a plurality of electric sensor cells in a spatially distributed manner within a locally restricted area above a substrate of said semiconductor device, said locally restricted area comprising functional areas comprising at least one of dummy circuit elements and functional circuit elements;
electrically accessing said sensor cells via a sensor interconnect structure formed at least partially in a metallization system of said semiconductor device so as to obtain an individual electric response from each of said sensor cells; and
evaluating a spatial variation of said at least one quality criterion of said semiconductor device on the basis of said individual electric responses.

19. The method of claim 18, wherein evaluating a spatial variation of said at least one quality criterion comprises determining a lateral variation of said at least one quality criterion.

20. The method of claim 19, wherein evaluating a spatial variation of said at least one quality criterion further comprises determining a variation along a height of said metallization system.

21. The method of claim 18, wherein evaluating a spatial variation of said at least one quality criterion comprises determining at least one resistance value for each of said plurality of sensor cells.

22. The method of claim 18, wherein electrically accessing said plurality of sensor cells comprises sequentially connecting different subsets of said plurality of sensor cells with external test equipment.

23. The method of claim 18, wherein providing said plurality of sensor cells comprises positioning said sensor cells within a die area of said semiconductor device.

24. The method of claim 18, wherein said sensor cells are electrically accessed prior to separating said semiconductor substrate into individual die.

25. The method of claim 18, wherein providing said plurality of sensor cells comprises forming a plurality of differently configured sensor elements in at least some of said plurality of sensor cells.
